(19) United States
(12) Patent Application Publication
(10) Pub. No.: US 2021/0181253 A1
(43) Pub. Date: Jun. 17, 2021

(54) Fail Density-Based Clustering for Yield Loss Detection

(71) Applicant: Texas Instruments Incorporated, Dallas, TX (US)

(72) Inventors: Istvan Bauer, Allen, TX (US); Michael Menne Haggerty, Dallas, TX (US); Scott Eric Riddle, Allen, TX (US); Peter W. Kinghorn, Denison, TX (US); Amit Nahar, Allen, TX (US); Glenn Edward Schuette, Allen, TX (US); Russell K. Kneupper, Missouri City, TX (US)

(21) Appl. No.: 17/096,898

(22) Filed: Nov. 12, 2020

Related U.S. Application Data
(60) Provisional application No. 62/948,371, filed on Dec. 16, 2019.

(51) Int. Cl. G01R 31/3185; G01R 31/317; G06K 9/62

(52) U.S. Cl. CPC G01R 31/318511; G06K 9/6226; G01R 31/31723; G01R 31/31718

(57) ABSTRACT

A method for failed die clustering is provided that includes extracting a data set of failed die on a wafer from a wafer map for the wafer, determining a density parameter for clustering the failed die, removing false failures from the data set of failed die to generate a reduced data set of failed die, locating clusters of failed die in the reduced data set by executing a density-based spatial clustering of applications with noise (DBSCAN) algorithm with the density parameter, and applying a guard band to each located cluster.

### CROSS-REFERENCE TO RELATED APPLICATIONS

This application claims benefit of U.S. Provisional Patent Application No. 62/948,371 filed Dec. 16, 2019, which is incorporated herein by reference in its entirety.

### BACKGROUND

Semiconductor wafers are typically tested for defective die prior to die packaging. Die defects may be caused, for example, by foreign particles, minute scratches, and/or imperfections introduced during photoresist, photomask, and diffusing operations applied to the wafer. Electrical probe testing is commonly used to locate defective die. The output of the electrical probe testing of a wafer is a wafer map that includes for each die an indication of whether or not the die passed the testing. Close neighbors of clusters of failed die may have passed electrical probe testing but are considered to be have a high probability of latent defects given their proximity to the clusters. Guard banding is performed for clusters of failed die in which such neighboring die in a band surrounding each cluster are each indicated as being included in a guard band.

### SUMMARY

Embodiments of the present disclosure relate to fail density based clustering of failed die on a semiconductor wafer. In one aspect, a method for failed die clustering is provided that includes extracting a data set of failed die on a wafer from a wafer map for the wafer, determining a density parameter for clustering the failed die, removing false failures from the data set of failed die to generate a reduced data set of failed die, locating clusters of failed die in the reduced data set by executing a density-based spatial clustering of applications with noise (DBSCAN) algorithm with the density parameter, and applying a guard band to each located cluster.

In one aspect, a system is provided that includes a non-transitory computer-readable medium storing software instructions for failed die clustering, wherein the software instructions include software instructions to extract a data set of failed die on a wafer from a wafer map for the wafer, determine a density parameter for clustering the failed die, remove false failures from the data set of failed die to generate a reduced data set of failed die, locate clusters of failed die in the reduced data set by executing a density-based spatial clustering of applications with noise (DBSCAN) algorithm with the density parameter, and apply a guard band to each located cluster, and at least one processor coupled to the non-transitory computer-readable medium to execute the software instructions.

In one aspect, a method for failed die clustering is provided that includes locating clusters of failed die in a data set of failed die of a wafer using a density-based spatial clustering of applications with noise (DBSCAN) algorithm, and applying a guard band to each located cluster.

### BRIEF DESCRIPTION OF THE DRAWINGS

FIG. 1 is a flow diagram illustrating an example wafer testing process;

FIG. 2 is a flow diagram of a method for failed die clustering and guard banding;

FIG. 3 is a flow diagram of a method for determining the density parameter for failed die clustering;

FIGS. 4A-4C are example wafer maps;

FIG. 5 is an example user interface;

FIG. 6 is a block diagram of an example wafer testing system; and

FIG. 7 is a block diagram of an example computer system 700 that may be used in the wafer testing system of FIG. 6.

### DETAILED DESCRIPTION

Specific embodiments of the disclosure are described herein in detail with reference to the accompanying figures. Like elements in the various figures are denoted by like reference numerals for consistency.

Embodiments of the disclosure provide functionality for automatically detecting clusters of failed die on a semiconductor wafer. The clustering is based on the density of the failed die on the wafer such that failed die in regions of low failure density on the wafer are not clustered while failed die in regions of high failure density are clustered. This approach to clustering may help minimize die loss on the wafer due to cluster detection as clustering in regions of low failure density may cause otherwise good die to be included in such clusters. Further, some embodiments provide for automatic guard banding of the detected clusters.

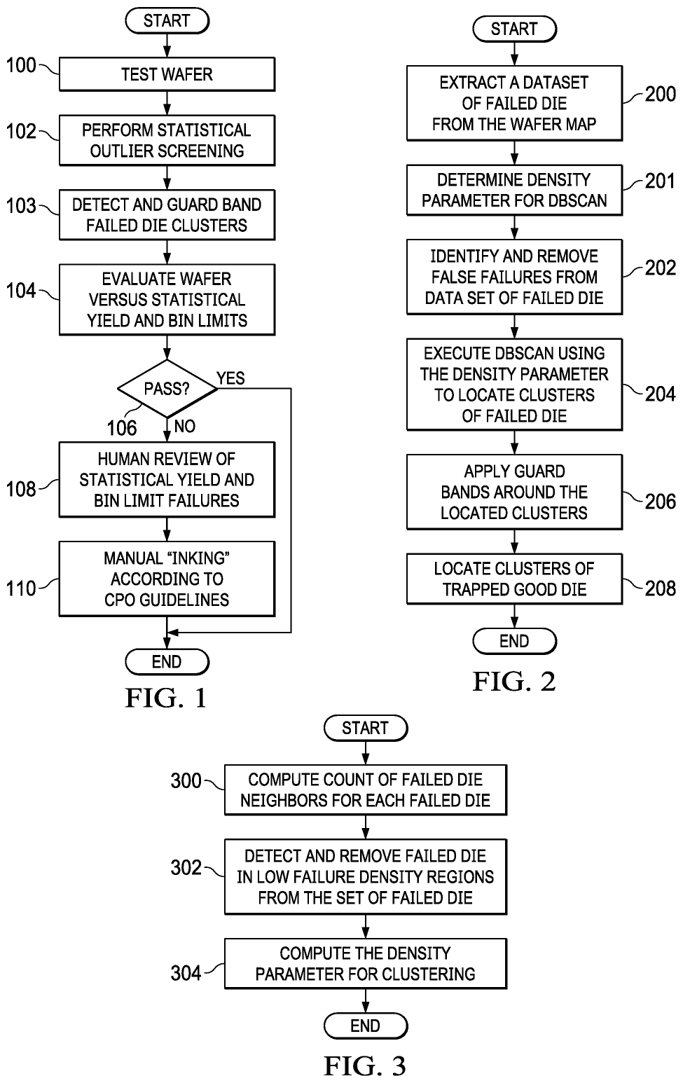

FIG. 1 is a flow diagram illustrating an example semiconductor wafer testing process in accordance with one or more embodiments. Initially, the wafer is electrically tested 100 using automatic test equipment such as a wafer prober. The output of the probe testing is a set of information about the test referred to as a wafer map. In addition to meta data such as the lot of the wafer, the stepping pattern used for testing the wafer, wafer orientation or rotation, etc., the wafer map also includes the location of each die using a coordinate system that corresponds to the physical structure of the wafer and the probe test result for each die. Based on the probe test results, each die is assigned to a bin. Any suitable approach to binning may be used. For example, bin 1 can include all good first grade die, bin 2 can include all good second grade die, bin 3 can include all plug die, bin 4 can include all bad or failed die, and bin 5 may include all edge bad die.

Statistical outlier screening is then performed 102. In general, statistical outlier screening is performed to identify outlier die that did not fail the electrical testing but are statistically at high risk for failure during operation. Some example techniques for statistical outlier screening are described in U.S. Pat. No. 7,129,735 entitled “Method for Test Data-Driven Statistical Detection of Outlier Semiconductor Devices,” U.S. Pat. No. 7,494,829 entitled “Identification of Outlier Semiconductor Devices using Data-Driven Statistical Characterization,” and U.S. Pat. No. 8,126,681 entitled “Semiconductor Outlier Identification Using Serially-Combined Data Transform Processing Methodologies.”

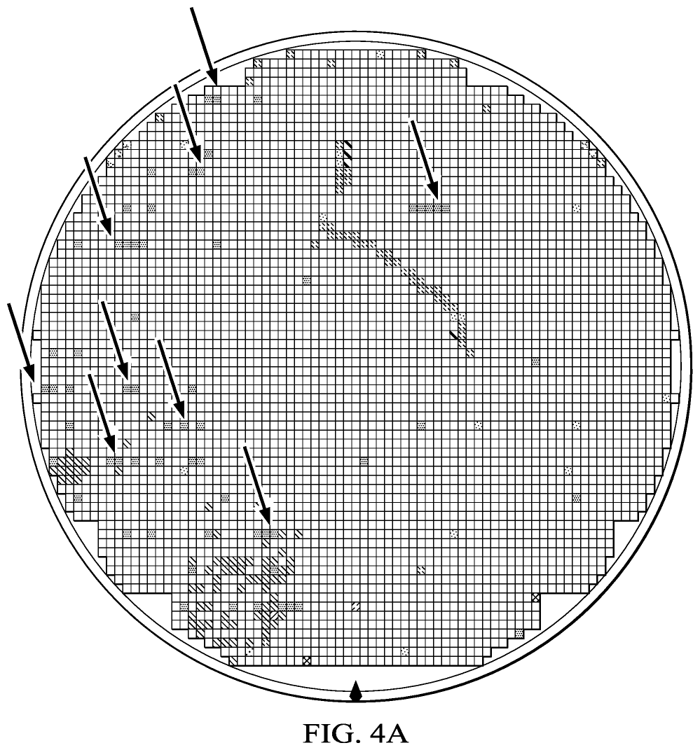

After the statistical outlier screening, failed die clusters are detected 103 and guard bands are applied to the clusters. An example method for clustering and guard banding is described herein in reference to FIG. 2 and FIG. 3.

The wafer is then evaluated 104 versus statistical yield and bin limits. A given die type has a distribution of the average statistical yield over time which is used to define the statistical yield and bin limits, i.e., the percentage yield for wafers of the die type. For example, if the average yield is 90% and the six sigma percentage is 80%, the wafer may undergo further scrutiny.

If the wafer does not pass 106 the evaluation, human review of the statistical yield and bin limit failures is performed and further manual “inking” 110 of the wafer may be performed prior to releasing the wafer for further processing. Although not specifically shown, if the failures are sufficiently high, the wafer may be scrapped. Manual “inking” may be performed by a user viewing a wafer map image on a display device and manually marking each die to be scrapped. This manual marking will then be indicated in the stored wafer map, e.g., by changing the bin of the “inked” die to a scrap bin. If the wafer passes 106, then the wafer is released for further processing.

FIG. 2 is a flow diagram of a method for failed die clustering and guard banding in accordance with one or more embodiments. The method identifies clusters of failed die in a data set of failed die on the wafer and automatically applies guard bands around each cluster. The cluster identification is performed using a well-known density based clustering algorithm, density-based spatial clustering of applications with noise (DBSCAN). A brief description of the algorithm is provided below. More detailed description may be found, for example, in Martin Ester, et al., “A Density-Based Algorithm for Discovering Clusters in Large Spatial Databases with Noise,” Proceedings of the Second International Conference on Knowledge Discovery and Data Mining, Aug. 2-4, 1996, Portland Oreg., pp. 226-231, which is incorporated by reference herein.

In DBSCAN, clusters are dense regions of points, e.g., die, in the data space, e.g., dense regions of failed die in the failed die data set, separated by regions of lower density. The algorithm is based on the intuitive notion of “clusters” and “noise”. The key idea is that for each point, e.g., die, of a cluster, a neighborhood within given radius of the point includes at least a minimum number of points in the data set. In general, DBSCAN finds and merges neighborhoods of points that exceed a specified density threshold to form clusters. The density threshold is defined by two parameters, the radius of the neighborhood (eps) and the minimum number of neighbors/points (minPts) within the radius of the neighborhood. The parameter minPts may be referred to as the density parameter herein. Given these two parameters, DBSCAN performs a “find and merge” process to locate clusters. Any points not assigned to a cluster are considered to be noise.

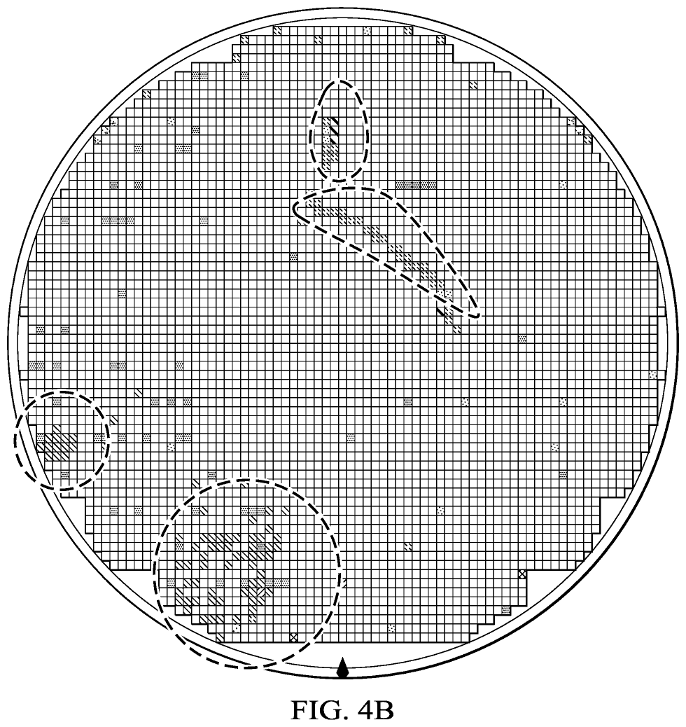

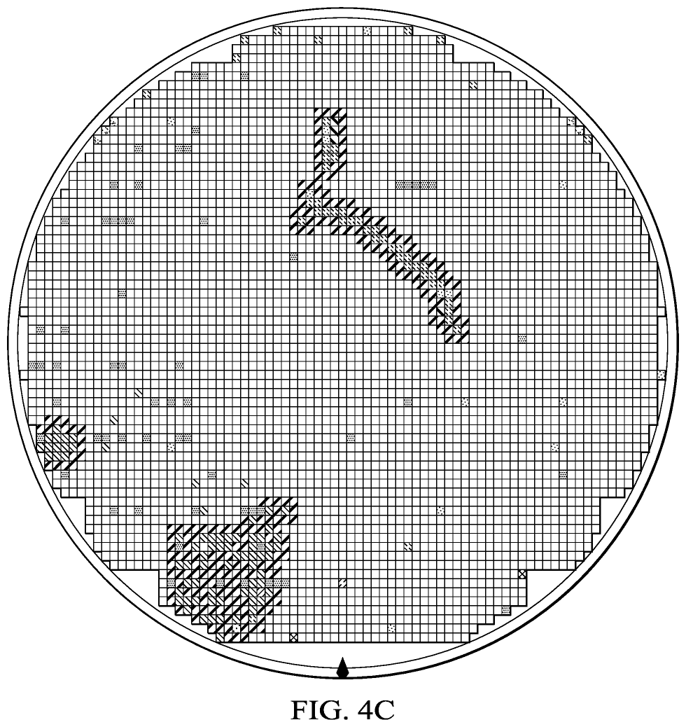

Referring again to FIG. 2, initially a data set of failed die is extracted 200 from a wafer map and the density parameter minPts is determined 201 for DBSCAN. A method for determining this parameter is described in reference to FIG. 3. Next, the wafer test results are processed 202 to identify “false failures” and such die are removed from the data set of failed die. False failures are die that were binned as failures due to issues in the test process rather than fabrication induced defects. For example, in the example wafer map of FIG. 4A, the die indicated by the arrows are all test related failures. Removing the false failures from the data set of failed die helps focus the clustering on the real fail signatures such as a scratch or a blob of high density failed die and may minimize die loss due to applying guard bands. The circled areas indicated in the example wafer map of FIG. 4B indicate areas of real fail signatures.

When a die fails a test or series of tests, the default assumption is that the die is bad. However, the cause of the failure may be due to, for example, a problem with the probe test hardware. For example, probe tips need to make contact with the correct force and position accuracy during simultaneous testing of multiple die. The failure of a single probe may cause one or more die to appear to have failed. Techniques for identifying false failures are well known and any such techniques now known or developed in the future may be used.

After false failures are detected and removed from the data set of failed die, DBSCAN is executed 204 on the data set of failed die to locate clusters of failed die. DBSCAN is executed using the previously determined density parameter minPts and eps=3. As previously mentioned, the parameter eps defines the radius of the neighborhood around a point. The radius of the neighborhood depends on the degrees of freedom (DOF) of the plane of the neighborhood, so eps=DOF+1. For two-dimensional (2D) applications such as a probe layout defined in a 2D field, DOF=2 and eps=3.

Guard bands are then applied 206 around the located clusters. The extent of each guard band, i.e., the die width of the guard band, may be fixed or may be specified by a user. For example, a guard band can be one die wide or two die wide for larger die sizes and may be increased significantly for very small die sizes. FIG. 4C illustrates the guard banding of the circled areas of the example wafer map of FIG. 4B. The boundary good die that form the guard band are saved as a guard band data set that is included in the wafer test information passed to the next step of wafer processing.

Clusters of good die that are trapped by the clusters of failed die are then located 208. When clusters of failed die are located and guard bands applied, small regions of ostensibly good die may be trapped, for example, between two clusters or between a cluster and the edge of the wafer. Such die may be marginal from a quality perspective and need to be identified so that they will not be used. To locate such regions, DBSCAN is executed on a data set of the remaining good die on the wafer, i.e., the good die identified by the wafer probe test less the good die used for the guard bands, to locate clusters of good die. For this execution of DBSCAN, eps=1 and minPts=1 in order to locate small clusters of good die as smaller clusters of good die are more likely to be trapped clusters.

The clusters of trapped die are identified using a threshold number of die. This threshold may be predetermined and/or user specified. The threshold value may be based, for example, on the size of the die and the total number of die on the wafer. For example, for a device with a very large die size, the threshold may be set to a minimal value while the threshold value may increase significantly for a device with a very small die size. The die in the located trapped clusters may be indicated as being of questionable quality, e.g., by designating them as scrap or assigning them to the guard band data set.

FIG. 3 is a flow diagram of a method for determining the density parameter for the DBSCAN clustering of the failed die in accordance with one or more embodiments. Initially, a count of failed die neighbors for each failed die in the failed die data set is computed 300. This count is a count of the number of failed die within a neighborhood of a radius of 3 around the die. The rationale for a radius of 3 is previously explained herein.

Failed die in low failure density regions of the wafer are also detected and removed 302 from the data set of failed die. For example, die having less than three failed die neighbors within a radius of three may be considered as being in low density areas. These failed die are removed from the data set in order to concentrate the clustering in the higher density areas.

The density parameter, i.e., minPts, for the DBSCAN clustering is then computed as per minPts=Average−Delta*StDev. Average is the average number of failed die neighbors for each failed die in the failed die data set and StDev is the standard deviation or measure of the dispersion of the failed die data set relative to the Average. Delta is an empirically determined coefficient used to differentiate between differences in density of wafers as the proximity of failed die has a different impact on low density wafers as compared to high density wafers. For example, Delta may be 1.5 for wafers having more than 2000 die and may otherwise be 1 for wafers having less than 200 die.

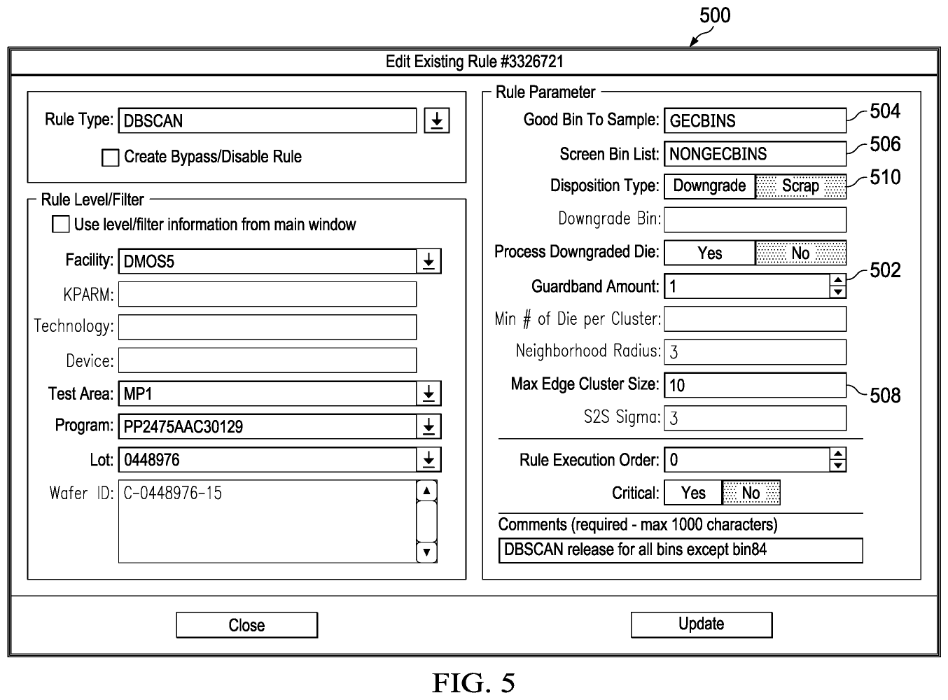

FIG. 5 is an example user interface 500 that may be used to modify the operation of the methods of FIG. 2 and FIG. 3. The Guardband Amount field 502 may be used to specify the extent or width of the guard bands to be applied. For example, the potentially impacted region around a cluster of failed die is inversely proportional to the size of the die. Accordingly, for very small die, the width of the guard band may be larger to cover all potentially marginal die as compared to the width of the guard band for larger die. The Good Bin to Sample field 504 may be used to input a list of bins that include good die. The Screen Bin List field 506 may be used to input a list of bins that include failed die that should be considered for clustering and guard banding. The Max Edge Cluster Size field 508 may be used to specify the threshold number of die for identifying clusters of trapped die. The Disposition Type field 510 may be used to define the bin type for die in the guard band data set.

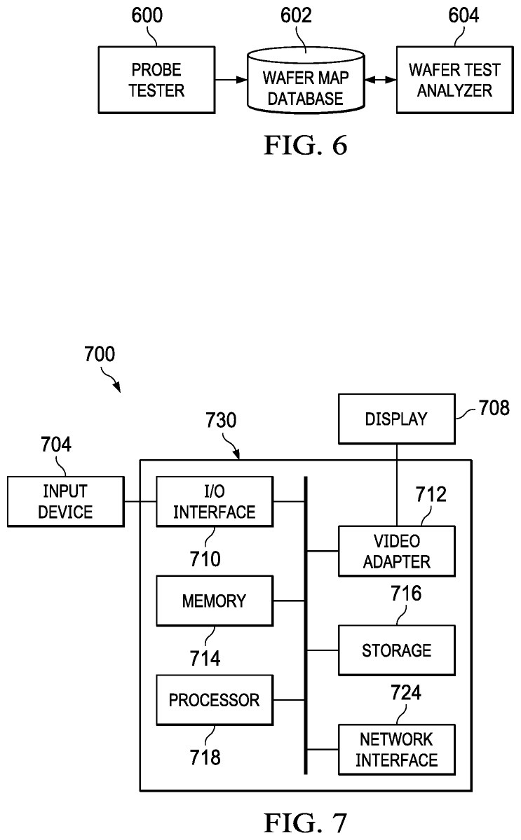

FIG. 6 is a block diagram of an example wafer testing system configured to perform the methods described herein. The probe tester 600 performs electrical probe testing of wafers and stores the resulting wafer maps in the wafer map database 602. The wafer test analyzer 604 is a computer system configured to execute software instructions that perform the methods of FIG. 2 and FIG. 3 to identify and guard band clusters of failed die on each probe tested wafer. The wafer test analyzer 604 accesses the wafer map for a wafer from the wafer map database 602, I, to extract the dataset of failed die, and updates the wafer map in the wafer map database 602 as needed, e.g., to indicate die in guard bands, in performing the methods of FIG. 2 and FIG. 3. In some embodiments, the wafer test analyzer 604 is further configured to provide a user interface such as that of FIG. 5 to allow a user to specify certain inputs to the methods.

FIG. 7 is a block diagram of an example computer system 700 that may be used as the wafer test analyzer 604 of FIG. 6. The computer system 700 includes a processing unit 730 coupled to one or more input devices 704 (e.g., a mouse, a keyboard, or the like), and one or more output devices, such as a display screen 708. In some embodiments, the display screen 708 may be touch screen, thus allowing the display screen 708 to also function as an input device. The processing unit 730 may be, for example, a desktop computer, a workstation, a laptop computer, a tablet, a dedicated unit customized for a particular application, a server, or the like. The display screen 708 may be any suitable visual display unit such as, for example, a computer monitor, an LED, LCD, or plasma display, a television, a high definition television, or a combination thereof. The display screen 708 can be used, for example, to display a user interface such as that of FIG. 5.

The processing unit 730 includes a processor 718, memory 714, a storage device 716, a video adapter 712, and an I/O interface 710 connected by a bus. The bus may be one or more of any type of several bus architectures including a memory bus or memory controller, a peripheral bus, video bus, or the like. The processor 718 may be any type of electronic data processor. For example, the processor 718 may be a processor from Intel Corp., a processor from Advanced Micro Devices, Inc., a Reduced Instruction Set Computer (RISC), an Application-Specific Integrated Circuit (ASIC), or the like. The memory 714, e.g., a non-transitory computer-readable medium, can be any type of system memory such as static random access memory (SRAM), dynamic random access memory (DRAM), synchronous DRAM (SDRAM), read-only memory (ROM), a combination thereof, or the like. Further, the memory 714 can include ROM for use at boot-up, and DRAM for data storage for use while executing programs.

The storage device 716, e.g., a non-transitory computer-readable medium, can include any type of storage device configured to store data, programs, and other information and to make the data, programs, and other information accessible via the bus. In one or more embodiments, the storage device 716 stores software instructions to be executed by the processor 718 to perform embodiments of the methods described herein. The storage device 716 may be, for example, one or more of a hard disk drive, a magnetic disk drive, an optical disk drive, a solid state drive, or the like.

The video adapter 712 and the I/O interface 710 provide interfaces to couple external input and output devices to the processing unit 730. The processing unit 730 also includes a network interface 724. The network interface 724 allows the processing unit 730 to communicate with remote units via a network (not shown). The network interface 724 may provide an interface for a wired link, such as an Ethernet cable or the like, or a wireless link. The computer system 700 may also include other components not specifically shown. For example, the computer system 700 may include power supplies, cables, a motherboard, removable storage media, cases, and the like.

### Other Embodiments

While the disclosure has been described with respect to a limited number of embodiments, those skilled in the art, having benefit of this disclosure, will appreciate that other embodiments can be devised which do not depart from the scope disclosed herein.

For example, embodiments are described herein referring to electrical probe testing of wafers. In some embodiments, optical testing may be used and/or a combination of electrical and optical testing may be used.

In another example, embodiments are described herein in which failed die in low failure density areas are removed from the failed die data set before clustering of the failed die is performed. In some embodiments, the removal of such failed die may be omitted as the presence of such die in the failed die data set may not affect the clustering process but may increase the processing time for completing the clustering of the failed die.

In another example, embodiments are described herein in which the density parameter minPts is computed for each wafer. In some embodiments, other techniques for specifying the density parameter may be used, such as, for example, allowing a user to specify the parameter or using a different formula for the computation.

In another example, embodiments are described herein in which all false failures are removed from the data set of failed die. In some embodiments, some false failures may not be removed.

In another example, embodiments are described herein in which trapped clusters of good die are located using DBSCAN with minPts=1 and eps=1. In other embodiments, different values of minPts and/or eps may be used.

Software instructions implementing embodiments of methods described herein may be initially stored in a non-transitory computer-readable medium and loaded and executed by one or more processors. In some cases, the software instructions may be distributed via removable non-transitory computer-readable media, via a transmission path from non-transitory computer-readable media on another digital system, etc. Examples of non-transitory computer-readable media include non-writable storage media such as read-only memory devices, writable storage media such as disks, flash memory, memory, or a combination thereof.

It is therefore contemplated that the appended claims will cover any such modifications of the embodiments as fall within the true scope of the disclosure.

What is claimed is:

1. A method for failed die clustering, the method comprising:
extracting a data set of failed die on a wafer from a wafer map for the wafer;
determining a density parameter for clustering the failed die;
removing false failures from the data set of failed die to generate a reduced data set of failed die;
locating clusters of failed die in the reduced data set by executing a density-based spatial clustering of applications with noise (DBSCAN) algorithm with the density parameter; and
applying a guard band to each located cluster.

2. The method of claim 1, further comprising removing failed die in low failure density regions of the wafer from the reduced data set prior to the locating clusters, wherein a failed die is in a low failure density region when the die has less than three failed die neighbors within a radius of three.

3. The method of claim 1, further comprising locating clusters of trapped good die and indicating that the trapped die are of questionable quality.

4. The method of claim 3, wherein locating clusters of trapped good die further comprises:
locating clusters of good die in a data set of good die on the wafer using the DBSCAN algorithm with minPts=1 and eps=1, wherein the data set of good die does not include any good die in the guard bands applied to the located clusters of failed die; and
identifying clusters of trapped good die in the clusters of good die using a threshold number of die.

5. The method of claim 4, wherein the threshold is specified by a user.

6. The method of claim 1, wherein determining a density parameter further comprises:
computing a count of failed die neighbors within a neighborhood of a radius of three for each failed die in the failed die data set; and
computing the density parameter based on an average count of failed die neighbors, a standard deviation of the counts of failed die neighbors, and a coefficient representing a relative density of the wafer.

7. The method of claim 1, wherein applying a guard band further comprises using a user specified width for the guard band.

8. The method of claim 1, wherein applying a guard band further comprises changing a bin of each die in the guard band to a user specified bin.

9. The method of claim 1, wherein the wafer map is generated by electrical probe testing of the wafer.

10. A system comprising:
a non-transitory computer-readable medium storing software instructions for failed die clustering, wherein the software instructions comprise software instructions to:
extract a data set of failed die on a wafer from a wafer map for the wafer;
determine a density parameter for clustering the failed die;
remove false failures from the data set of failed die to generate a reduced data set of failed die;
locate clusters of failed die in the reduced data set by executing a density-based spatial clustering of applications with noise (DBSCAN) algorithm with the density parameter; and
apply a guard band to each located cluster; and
at least one processor coupled to the non-transitory computer-readable medium to execute the software instructions.

11. The system of claim 10, wherein the software instructions further comprise software instructions to remove failed die in low failure density regions of the wafer from the reduced data set prior to locating clusters of failed die, wherein a failed die is in a low failure density region when the die has less than three failed die neighbors within a radius of three.

12. The system of claim 10, wherein the software instructions further comprise software instructions to locate clusters of trapped good die and to indicate that the trapped die are of questionable quality.

13. The system of claim 12, wherein the software instructions to locate clusters of trapped good die further comprise software instructions to:
locate clusters of good die in a data set of good die on the wafer using the DBSCAN algorithm with minPts=1 and eps=1, wherein the data set of good die does not include any good die in the guard bands applied to the located clusters of failed die; and
identify clusters of trapped good die in the clusters of good die using a threshold number of die.

14. The system of claim 10, wherein the software instruction to determine a density parameter further comprise software instructions to:
compute a count of failed die neighbors within a neighborhood of a radius of three for each failed die in the failed die data set; and
compute the density parameter based on an average count of failed die neighbors, a standard deviation of the counts of failed die neighbors, and a coefficient representing a relative density of the wafer.

15. The system of claim 10, wherein the wafer map is generated by electrical probe testing of the wafer.

16. A method for failed die clustering, the method comprising:
locating clusters of failed die in a data set of failed die of a wafer by executing a density-based spatial clustering of applications with noise (DBSCAN) algorithm; and
applying a guard band to each located cluster.

17. The method of claim 16, further comprising removing at least some false failures from the data set of failed die prior to the locating clusters.

18. The method of claim 16, further comprising removing failed die in low failure density regions of the wafer from the data set of failed die prior to the locating clusters, wherein a failed die is in a low failure density region when the die has less than three failed die neighbors within a radius of three.

19. The method of claim 16, further comprising determining a density parameter for DBSCAN based on a count of failed die neighbors of each failed die in the data set of failed die.

20. The method of claim 16, further comprising locating clusters of trapped good die using DBSCAN and indicating that the trapped die are of questionable quality.
